(19) United States
(12) Patent Application Publication
(10) Pub. No.: US 2019/0115241 A1
(43) Pub. Date: Apr. 18, 2019

(54) HYDROPHOBIC ELECTROSTATIC CHUCK

(71) Applicant: APPLIED MATERIALS, INC., Santa Clara, CA (US)

(72) Inventors: Kim VELLORE, San Jose, CA (US); Douglas A. BUCHBERGER, JR., Livermore, CA (US); Niranjan Kumar, Santa Clara, CA (US); Seshadri RAMASWAMI, Saratoga, CA (US)

(21) Appl. No.: 15/782,650

(22) Filed: Oct. 12, 2017

(51) Int. Cl. H01L 21/683; H01L 21/67; H01L 21/673; C23C 8/16

(52) U.S. Cl. CPC H01L 21/6833; H01L 21/67098; C23C 8/16; H01L 21/67316; H01L 21/67219

(57) ABSTRACT

The present disclosure relates to an electrostatic chuck, including: a base having a dielectric first surface to support a substrate thereon during processing; and an electrode disposed within the base proximate the dielectric first surface to facilitate electrostatically coupling the substrate to the dielectric first surface during use, wherein the dielectric first surface is sufficiently hydrophobic to electrostatically retain the substrate to the dielectric first surface when contacted with water. Methods of making and using the electrostatic chuck under wet conditions are also disclosed.

### FIELD

Embodiments of the present disclosure generally relate to an electrostatic chuck (e-chuck) for retaining a substrate on a hydrophobic surface.

### BACKGROUND

As the critical dimensions for electronic substrates continue to shrink in thickness, there is an increased need for semiconductor process equipment that can adequately support and process substrates such as those disposed in a wash.

An electrostatic chuck may be portable or physically located and fixed within a process chamber to generally support and retain a substrate in a stationary position during processing. However, the inventors have observed that substrates under wet conditions, such as wash conditions, often de-chuck as water or other conductive liquid may break the clamping bond of the e-chuck. De-chucking under wet conditions is problematic due to the risk of damaging a substrate beyond repair, especially in the case of ultra-thin substrates.

Therefore, the inventors have provided improved embodiments of electrostatic chucks.

### SUMMARY

Embodiments of electrostatic chucks and methods of use are provided. In some embodiments, an electrostatic chuck, includes: a base having a dielectric first surface to support a substrate thereon during processing; and an electrode disposed within the base proximate the dielectric first surface to facilitate electrostatically coupling the substrate to the dielectric first surface during use, wherein the dielectric first surface is sufficiently hydrophobic to electrostatically retain the substrate to the dielectric first surface when contacted with water.

In some embodiments, an electrostatic chuck, includes: a base having a dielectric first surface to support a substrate thereon during processing; and an electrode disposed within the base proximate the dielectric first surface to facilitate electrostatically coupling the substrate to the dielectric first surface during use, wherein the dielectric first surface is sufficiently hydrophobic to electrostatically retain the substrate to the dielectric first surface when contacted with water, wherein the dielectric first surface includes a super hydrophobic coating including branched polysilicate structures and hydrophobic ligands, and wherein the dielectric first surface has a contact angle of at least 140 degrees, at least 150 degrees, at least 160 degrees, or at least 170 degrees when contacted with water.

In some embodiments, a method of electrostatically chucking a substrate, includes: electrostatically chucking a substrate to a base having a dielectric first surface to support a substrate thereon during processing; and an electrode disposed within the base proximate the dielectric first surface to facilitate electrostatically coupling the substrate to the dielectric first surface during use, wherein the dielectric first surface is sufficiently hydrophobic to electrostatically retain the substrate to the base. The electrostatic chuck is as described in any of the embodiments disclosed herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic side view diagram of an electrostatic chuck in accordance with the present disclosure.

FIG. 2 is a cross-sectional side view diagram of a portion of an electrostatic chuck in accordance with the present disclosure.

FIG. 3 is a schematic side view diagram of a portable electrostatic chuck in accordance with the present disclosure different than FIG. 1.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure provide improved substrate supports that reduce or eliminate substrate damage due to undesired de-chucking in wet or wash conditions as compared to conventional substrate supporting apparatus. Embodiments of the present disclosure may advantageously avoid or reduce undesirable de-chucking during a wash process, which can further limit or prevent substrate warpage and non-uniformity. Embodiments of the present disclosure may be used to reduce or eliminate undesirable de-chucking of one or more ultra-thin substrates (e.g., between about 10 to 200 microns thick) and/or one or more die (e.g., die may have full thickness such from 1 mm to 10 microns) by retaining one or more substrates or die on a hydrophobic surface or super hydrophobic surface during wash processing, such as when contacted with water.

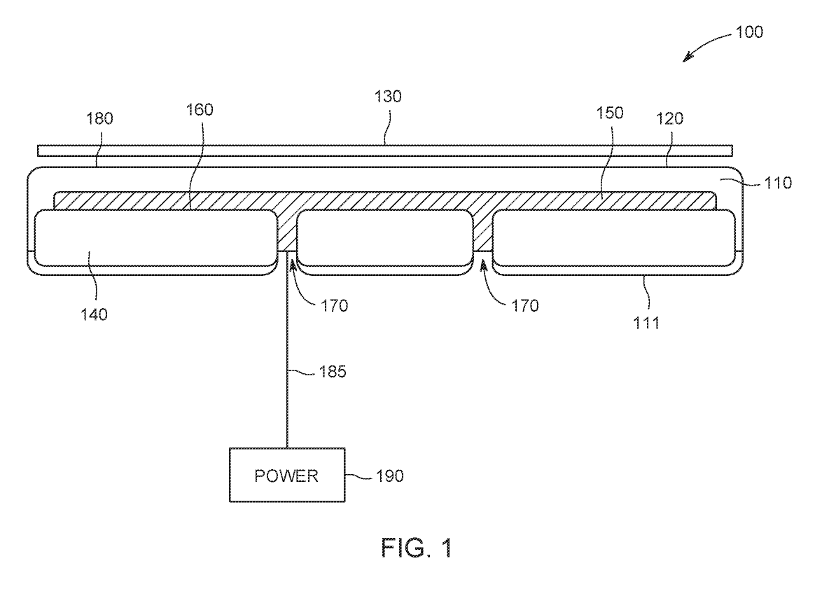

FIG. 1 is a schematic side view diagram (FIG. 1 is crosshatched to provide contrast) of an electrostatic chuck 100 showing a base 110 having a dielectric first surface 120 to support a workpiece or substrate 130 thereon during processing. The electrostatic chuck 100 may be moved into a load or unload station in a process chamber and supported by pedestal support (not shown in FIG. 1). The electrostatic chuck 100 is configured to electrostatically retain substrate 130. FIG. 1 shows substrate 130 above first surface 120 for clarity of the drawing, however, in use, substrate 130 is disposed upon first surface 120. In some embodiments, a bias voltage may be applied to the electrostatic chuck 100 outside of a process chamber to electrostatically fix the substrate 130 to the electrostatic chuck 100. In some embodiments consistent with the present disclosure, continuous power does not need to be applied to the electrostatic chuck 100 in order to electrostatically fix substrate 130 to the electrostatic chuck 100 (e.g., a bias voltage may be applied once or intermittently as needed.) Once the substrate 130 is electrostatically fixed to the electrostatic chuck 100 in a load station, the electrostatic chuck 100 may be moved into and out wet conditions in order to process the substrate. In embodiments, power source 190 may be included having a fixed DC power source, such as a fixed battery, a DC power supply, a power charging station, or the like.

The thickness of the electrostatic chuck 100 is selected to provide sufficient stiffness to the substrate 130 disposed on the electrostatic chuck 100, for example a substrate 130 such as an ultra-thin substrate can be processed in one or more process chambers without damaging the ultra-thin substrate. In some embodiments, the electrostatic chuck 100 may be portable and/or sized such that the electrostatic chuck 100 plus the substrate 130 (e.g., wafer or die) together have a thickness of about 0.7 mm (i.e., the same as typical wafer or die substrates currently processed) and may be handled in the same manner as typical wafer or die processing. In embodiments, electrostatic chuck is configured to be portable such that the electrostatic chuck can be handled and moved by substrate processing equipment. In embodiments, portable electrostatic chucks are suitable for transporting the substrate from a first location to a second location. In embodiments, the dielectric first surface 120 of the electrostatic chuck can be substantially rectangular or square, and may have a support surface area on the order of 100 square millimeters (mm²) to about 3 square meters (m²).

In some embodiments, the electrostatic chuck 100 may be used in a horizontal processing chamber (not shown in FIG. 1) such that the electrostatic chuck 100 supports the substrate 130 substantially parallel to the ground. In other embodiments, the electrostatic chuck 100 is used in a vertical processing chamber (not shown in FIG. 1) such that the electrostatic chuck 100 supports the substrate 130 substantially perpendicular to the ground. Since the electrostatic chuck 100 retains the substrate 130 thereon, the electrostatic chuck 100 may be held or moved in any orientation without damaging the substrate 130. In some portable embodiments, a conveyer system (e.g., robotic assembly, rollers, etc. (not shown in FIG. 1)) may be used to move the electrostatic chuck 100 into and out of openings in the various process chambers. Although directional terms such as top and bottom may be used herein for descriptive purposes of various features, such terms do not limit embodiments consistent with the present disclosure to a specific orientation.

Still referring to FIG. 1, the electrostatic chuck 100 includes a carrier 140 which may be fabricated of materials including, e.g., glass, polysilicon, gallium arsenide, aluminum oxide (Al₂O₃), aluminum nitride (AlN), silicon (Si), germanium, silicon-germanium, stainless steel, aluminum, ceramic, a nickel iron alloy having a low coefficient of thermal expansion (such as 64FeNi, for example, INVAR®), or the like. These materials are strong and easy to machine, and may be used with existing wafer processing tools. In embodiments, the carrier is prepared by thinning, or by drilling or etching through holes 170. In embodiments, the carrier 140 may be a standard silicon wafer of any desired shape or size such as around 300 mm wafer.

If the carrier material is a dielectric, electrode 150 for the electrostatic chuck 100 (e.g., a chucking electrode) can be directly deposited on the carrier 140. In embodiments where the carrier material is not a dielectric, a dielectric layer (not shown in FIG. 1) may be disposed between carrier 140 and electrode 150.

In some embodiments, the carrier 140 is fabricated of the same material as the substrate 130, or a material that has a substantially equivalent coefficient of thermal expansion as the material used for the substrate 130, such as within about 10%, or about 5%, or about 1%. Providing the same or similar coefficient of thermal expansion will advantageously prevent cracking of the substrate and non-uniform thermal expansion or deformation of the substrate when both the carrier 140 and substrate 130 are heated during substrate processing.

In some embodiments, suitable carriers 140 include carriers available from Ceratec Inc. of Santa Clara, Calif. and Fralock, Inc. of Valencia, Calif. Fralock carriers may optionally include a polyimide coating (not shown in FIG. 1) attached or adhered to the carrier 140.

The thickness of carrier 140 is sized to provide sufficient stiffness to the electrostatic chuck 100 such that when the substrate 130 is disposed on the electrostatic chuck 100, the substrate 130 can be processed/handled as a sheet in existing process chambers. In some embodiments, the thickness of carrier 140 should match the thickness of conventional substrates processed for a specific type of substrate. For example, for wafer applications, the thickness of carrier 140 and substrate 130 should match the thickness of conventional wafer substrates (e.g., about 0.4-0.7 mm). By making the thickness of carrier 140 and substrate 130 match the thickness of conventional substrates processed for a specific type of substrate, the flexible, substrate 130 is advantageously able to be handled and processed in tools that are designed to handle rigid substrates. In some embodiments, the thickness of the electrostatic chuck 100 is inclusively between about 100 to 1000 microns less than 0.4 mm and about 10 to 200 microns less than 0.7 mm.

Still referring to FIG. 1, electrode 150 is shown as an electrically conductive layer disposed within the base 110 proximate the dielectric first surface 120 to facilitate electrostatically coupling the substrate 130 to the dielectric first surface 120 during use. Electrode 150 shown as an electrically conductive layer disposed on a first surface 160 of the carrier 140. Electrode 150 may be fabricated of any electrically conductive material suitable for use in substrate processing and substrate processing equipment, such as, e.g., aluminum (Al), copper (Cu), molybdenum (Mo), tungsten, etc. In some embodiments, the electrode 150 has a thickness between about 100 nm and about 20 microns. In embodiments, electrode 150 can be bi-polar or mono-polar.

Electrode 150 may be deposited and patterned to form a chucking electrode. Electrode 150 may be patterned to form a single electrode, or a plurality of electrodes (not shown in FIG. 1). For example, in some embodiments the electrode 150 may be patterned to form a plurality of chucking electrodes positioned to retain a plurality of substrates 130 on a single carrier 140. For example, a plurality of substrates 130 may be held in an array on the electrostatic chuck 100 such that the plurality of substrates 130 may be simultaneously processed (not shown in FIG. 1).

Still referring to FIG. 1, electrostatic chuck 100 includes a base 110 disposed over the electrode 150, such that the electrode 150 is disposed between the carrier 140 and the dielectric first surface 120. In embodiments, base 110 is a layer of dielectric material (e.g., alumina (Al₂O₃), silicon oxide (SiO₂), silicon nitride (SiN), glass, ceramic or the like) disposed over the electrode 150 to provide a dielectric first surface 120 for the substrate 130. The base 110 may be fabricated of the same material as the substrate 130 and/or carrier 140, or a material that has a substantially equivalent coefficient of thermal expansion as the material used for the substrate 130 and/or carrier 140. In embodiments, base 110 supports the substrate 130 substantially parallel to a dielectric first surface 120 of the electrostatic chuck 100 when the substrate 130 is disposed on the electrostatic chuck 100. In some embodiments, the base 110 has a thickness between about 100 nm and about 0.2 mm. The thickness of the base 110 may be varied depending on the electrostatic chucking force and resistivity desired. For example, the thicker the base 110, the lower the electrostatic chucking force. The lower the resistivity, the longer the electrostatic chuck 100 will hold a substrate without recharging. In embodiments, base 110 includes a material that has a coefficient of thermal expansion similar to silicon.

In embodiments, base 110 is a dielectric layer deposited over electrode 150. The dielectric layer may protect the electrode and provide an insulating layer to maintain the electrostatic charge when a substrate 130 is being electrostatically held to the electrostatic chuck 100. The base 110 may be deposited in a variety of different ways. In embodiments, carrier 140 is encapsulated, or surrounded on all sides by base 110 being expanded to include base portion 111.

In embodiments, the dielectric first surface 120 of the the base 110 is sufficiently hydrophobic to electrostatically retain the substrate 130 to the electrostatic chuck 100 when contacted with water. Hydrophobic and hydrophobicity refer to the wettability of dielectric first surface 120 (e.g., a coating surface or smooth surface) that has a water contact angle of approximately 85° or more. Super hydrophobic and super hydrophobicity refer to the wettability of dielectric first surface 120 (e.g., a coating surface or smooth surface) that has a water contact angle of approximately 150° or more. In embodiments, a low contact angle hysteresis (ΔΘ=Θ_{ADV}−Θ_{REC}<5° further characterizes the super hydrophobicity. Typically, on a hydrophobic surface, for example, a 2-mm-diameter water drop beads up but does not run off the surface when the surface is tilted moderately. As the surface is tilted, the wetting angle at the downhill side of the droplet increases, while the wetting angle at the uphill side of the droplet decreases. Due to difficulty for the advancing (downhill) interface to push forward onto the next increment of solid surface and the difficulty for the receding (uphill) interface to let go of the portion of solid surface upon which the droplet is disposed, the droplet tends to remain stationary or pinned in place. A hydrophobic surface is described as having a low contact angle hysteresis if the difference between advancing and receding contact angles is less than 5°. The ability for water droplets to slide or roll on a superhydrophobic surface leads to a self-cleaning mechanism where deposits or surface contaminants are removed by the water droplets as they slide or roll over the surface. In embodiments the contact angle is measured by methods know in the art such as using a goniometer.

In embodiments, the substrate may be retained on the dielectric first surface 120 when being contacted with water flowing thereon at a rate between 3 to 10 liters per minute, or rate of at least 1 liter per minute, or at least 2 liters per minute, or at least 3 liters per minute, or 4 liters per minute, at about 55 psi.

In embodiments, the dielectric first surface 120 is polished or smoothed to a surface finish characterized as having a surface roughness (Ra) of about 8 microinches or below, such as about 0.5 to 8 microinches, about 5 to 8 microinches, or about 3 to 7 microinches. In embodiments, the surface finish in accordance with the present disclosure increases the contact angle thereof by at least 10 degrees, at least 20 degrees, at least 30 degrees, at least 50 degrees, at least 60 degrees, at least 70 degrees, or at least 80 degrees when contacted with water. In embodiments, dielectric first surface 120 has a contact angle in an amount of 100 to 170 degrees when contacted with water. In embodiments, the dielectric first surface includes a contact angle of at least 100 degrees, at least 110 degrees, at least 120 degrees, at least 130 degrees, at least 140 degrees, at least 150 degrees, at least 160 degrees, or at least 170 degrees when contacted with water. In embodiments, dielectric first surface 120 has a contact angle in an amount of 150 to 170 degrees when contacted with water. In embodiments, dielectric first surface 120 has a contact angle in an amount of 160 to 170 degrees when contacted with water. In embodiments, dielectric first surface 120 has a contact angle in an amount of 180 degrees or higher when contacted with water.

In embodiments, dielectric first surface 120 includes a coating 180 such as a hydrophobic coating or super hydrophobic coating in order for the dielectric first surface 120 to be sufficiently hydrophobic to electrostatically retain the substrate 130 to the dielectric first surface 120 when contacted with water. Suitable coatings can be fabricated from solution or hydrophilic polysilicate gel capable being applied to dielectric first surface 120. Suitable solutions of gels include a hydrophobic or super hydrophobic compositions capable of forming a layer of coating and adhering to dielectric first surface 120. In embodiments, a hydrophobic coating includes silane, siloxane, or combinations thereof. In embodiments, a super hydrophobic coating includes branched polysilicate structures and hydrophobic ligands. In embodiments, coating solution may be diluted with an alcohol to tailor the hydrophobic coating solution to a given coating deposition method. In certain embodiments, additional solvents may be added to impart a slower evaporation rate to the coating solution. Suitable solvents may include propylene glycol monomethyl ether, tetrahydrofuran, dioxane, or diethoxyethane, which optionally may be added in combination to obtain specific solvent evaporation characteristics.

In embodiments deposition of the hydrophobic or super hydrophobic coating solution upon dielectric first surface 120 is achieved using a variety of coating methods known to those skilled in the art. These can include dip-coating, spin-coating, spray-coating, flow-coating, aerosol deposition via a propellant, ultrasonic aerosolizing of the coating solution, or the like. The drying time of the coating solution is solvent choice dependent, but in most embodiments drying occurs within 10 minutes of deposition of the solution. The coating solution can be dried under ambient conditions or in the presence of heat and airflow to aid the drying process per the specific application.

In embodiments, dielectric first surface 120 and coating 180 may include a super hydrophobic coating having a water contact angle of at least about 150° and a contact angle hysteresis of less than about 5°. The deposited super hydrophobic coating may include a nanoporous metal oxide imparted with hydrophobic ligands or oleophobic ligands. The pore size is in the range from approximately 5 nm to 1 micron. In various embodiments, each of the one or more super hydrophobic coatings may include polysilicate structures which may include a three dimensional network of silica particles having surface functional groups derivatized with a silylating agent and a plurality of pores. Exemplary silylating agent can include, but are not limited to, trimethylchlorosilane, trichloromethylsilane, trichlorooctylsilane, hexamethyldisilazane, or any reactive silane including at least one hydrophobic ligand. In some embodiments, one or more super hydrophobic coatings may be disposed upon dielectric first surface 120 which may be the same in terms of chemical composition and thickness. In certain embodiments, at least one of the one or more hydrophobic and/or super hydrophobic coatings can be different in terms of chemical composition and thickness. In various embodiments, each of the one or more hydrophobic or super hydrophobic coatings can have a thickness from about 10 nanometers (0.01 microns) to about 3 microns.

In accordance with various embodiments of the present disclosure, hydrophobic coating solution or hydrophobic polysilicate gel suitable for topical application to dielectric first surface 120 include those available from Lotus Leaf Coatings, Inc., of Albuquerque N. Mex. In embodiments, HYDROFOE™ brand super hydrophobic coating is suitable for use in accordance with the present disclosure, and upon curing provides contact angles between 150° and 170°. Such coatings may have a thickness of less than 1 micron, a heat resistance up to about 350° C., a high optical clarity of 93% to 95%, and stability under UV exposure.

In embodiments, the dielectric first surface 120 is coated as described above to increase the contact angle thereof by at least 10 degrees, at least 20 degrees, at least 30 degrees, at least 50 degrees, at least 60 degrees, at least 70 degrees, or at least 80 degrees when contacted with water. In embodiments, dielectric first surface 120 is coated as described herein to have a contact angle in an amount of 100 to 170 degrees when contacted with water. In embodiments, the dielectric first surface includes a contact angle of at least 100 degrees, at least 110 degrees, at least 120 degrees, at least 130 degrees, at least 140 degrees, at least 150 degrees, at least 160 degrees, or at least 170 degrees when contacted with water. In embodiments, dielectric first surface 120 is coated to have a contact angle in an amount of 150 to 170 degrees when contacted with water. In embodiments, dielectric first surface 120 is coated to have a contact angle in an amount of 160 to 170 degrees when contacted with water. In embodiments, dielectric first surface 120 has a contact angle in an amount of 180 degrees or higher when contacted with water.

Alternatively or in combination with the coating disclosed above, in some embodiments, the substrate 130 may also be coated as described herein. Coatings as described above may be provided to the portion of the substrate 130 adjacent to dielectric first surface 120, such as a back side, or non-processing side, of the substrate 330. In embodiments, substrate 130 is coated as described above to increase the contact angle thereof by at least 10 degrees, at least 20 degrees, at least 30 degrees, at least 50 degrees, at least 60 degrees, at least 70 degrees, or at least 80 degrees when contacted with water. In embodiments, substrate 130 is coated as described herein to have a contact angle in an amount of 100 to 170 degrees when contacted with water. In embodiments, the substrate 130 includes a contact angle of at least 100 degrees, at least 110 degrees, at least 120 degrees, at least 130 degrees, at least 140 degrees, at least 150 degrees, at least 160 degrees, or at least 170 degrees when contacted with water. In embodiments, substrate 130 is coated to have a contact angle in an amount of 150 to 170 degrees when contacted with water. In embodiments, substrate 130 is coated to have a contact angle in an amount of 160 to 170 degrees when contacted with water. In embodiments, substrate 130 has a contact angle in an amount of 180 degrees or higher when contacted with water.

In embodiments, by coating the substrate 130 as described above, the substrate is retained to the dielectric first surface 120 when contacted with water. For example, the substrate may be retained on the dielectric first surface 120 when being contacted with water flowing thereon at a rate between 3 to 10 liters per minute, or rate of at least 1 liter per minute, or at least 2 liters per minute, or at least 3 liters per minute, or 4 liters per minute at about 55 psi.

In embodiments, only the substrate may be coated as described herein to retain the clamp of the workpiece to the electrostatic chuck, provided the dielectric layer is sufficiently hydrophobic without a coating.

In embodiments, the dielectric first surface is polished to increase a contact angle by at least 10 degrees when contacted with water. For example, a ceramic surface may be lapped to get a fine finish.

Still referring to FIG. 1, the electrostatic chuck 100 further includes at least one conductor 185 coupled to the electrode 150. The at least one conductor 185 may be coupled to a power source 190. In some embodiments, when power from power source 190 is applied to the at least one conductor 185, a bias to the electrostatic chuck 100 relative to the substrate 130 is provided which electrostatically attracts the substrate 130 to the electrostatic chuck 100 sufficient to retain the substrate 130 thereon. In some embodiments, the number of conductors 285 is two.

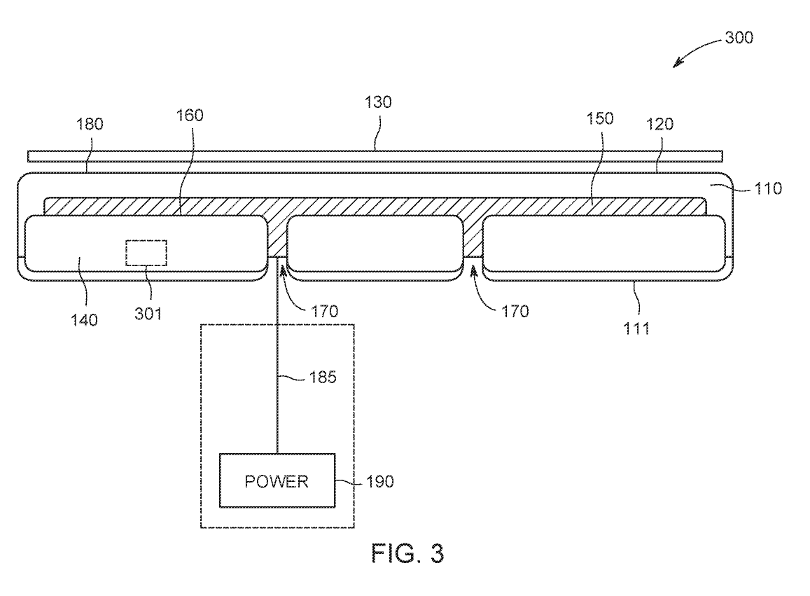

Referring now to FIG. 3 (FIG. 3 is crosshatched to provide contrast), a power source is provided as a portable battery power source 301 coupled to the electrostatic chuck 100. The portable battery power source 301 may be disposed within carrier 140. In embodiments, a portable battery power source 301 may move with electrostatic chuck 100 such as when electrostatic chuck 100 is portable and carries the substrate 130, for example, into and out of one or more process chambers. In embodiments, the electrostatic chuck 100 having a portable battery power source 301 may also optionally include a power source 190 such as a fixed DC power source, a fixed battery, a DC power supply, a power charging station, or the like. In embodiments, portable battery power source 301 may be coupled to the electrode 150 to provide a bias to the electrostatic chuck 100 relative to the substrate 130 which electrostatically retains the substrate 130 to the electrostatic chuck 100 when contacted with water.

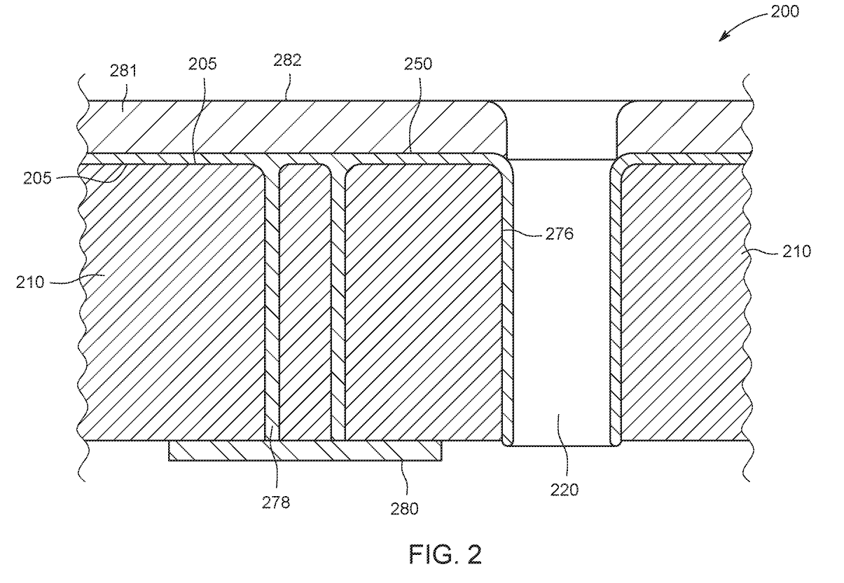

Referring now to FIG. 2, a cross-sectional side view diagram of a portion of an electrostatic chuck 200 showing an example of two types of holes that may be used with the electrostatic chuck 200. A carrier 210, such as a silicon wafer as described above, has a large through hole 220 that extends through the carrier 210. An electrode 250 such as an electrode layer is applied over the carrier 210 after the though hole 220 has been made. Deposited metal as described above, on the first surface 205 of the carrier 210 serves as electrode 250. In embodiments, the electrode 250 extends into the large through hole and lines or plates sides 276 of the through hole. The larger hole 220 may also be used for vacuum ports, lift pins, and other purposes. Another second hole 278 is smaller and filled with a metal layer such that the metal filled second hole provides an electrical connection to the electrode 250. In some embodiments, the base includes one or more larger holes 220 formed therethrough. In some embodiments, the larger holes 220 may be configured as gas diffusion holes or lift pin holes to facilitate de-chucking.

Still referring to FIG. 2, the backside electrical access may be improved by including conductive bond pad 280 over one or more of the holes 278. The bond pad 280 may be formed by metal deposition, printing, or other ways known in the art. The bond pad 280 provides a secure connection to electrical leads (such as conductor 185 shown in FIG. 1). The electrical leads may be used to apply a current to the electrode 250 to electrostatically charge the electrode 250 to hold a substrate to the chuck and to remove the electrostatic charge when de-chucking the substrate.

A dielectric layer 281 having a dielectric first surface 282 is applied over the electrode 250 to maintain the electrostatic charge. Dielectric layer 281 can be similar to base 110 and dielectric first surface 120, described above with respect to FIG. 1. Dielectric first surface 282 may be modified such that is sufficiently hydrophobic to electrostatically retain the substrate to the dielectric first surface 282 when contacted with water. In embodiments, dielectric first surface 282 is smoothed or coated as describe above.

The present disclosure also relates to a method of electrostatically chucking an ultra-thin substrate, including: electrostatically chucking a substrate to a base having a dielectric first surface to support a substrate thereon during processing; and an electrode disposed within the base proximate the dielectric first surface to facilitate electrostatically coupling the substrate to the dielectric first surface during use, wherein the dielectric first surface is sufficiently hydrophobic to electrostatically retain the substrate to the base when contacted with water. In embodiments, the methods include applying a first power to the electrode to provide a bias base relative to the substrate. Embodiments, include contacting dielectric first surface and electrostatically retained substrate with water; and performing a de-chucking process to release the substrate from the dielectric first surface. In embodiments, methods include de-chucking by providing a gas between the dielectric first surface and the substrate to release the substrate from the dielectric first surface.

The present disclosure also relates to methods of manufacturing and/or refurbishing an electrostatic chuck. Such methods include providing an electrostatic chuck having a base with a dielectric first surface to support a substrate thereon during processing. The dielectric first surface may be modified to be sufficiently hydrophobic to electrostatically retain the substrate to the dielectric first surface when contacted with water. In embodiments, the dielectric first surface is modified by at least one of polishing the dielectric first surface to increase a contact angle by at least 10 degrees, or coating the dielectric first surface as described above. During use or over time, the hydrophobicity of the dielectric surface may undesirably decrease due to wear of the dielectric surface and/or any coatings disposed thereon. As such, in some embodiments, the electrostatic chuck may be refurbished by repeating the above-noted process to at least one of polish the dielectric first surface to increase a contact angle by at least 10 degrees, or coat the dielectric first surface as described above.

While the foregoing is directed to embodiments of the present disclosure, other and further embodiments of the disclosure may be devised without departing from the basic scope thereof.

1. An electrostatic chuck, comprising:
a base having a dielectric first surface to support a substrate thereon during processing; and
an electrode disposed within the base proximate the dielectric first surface to facilitate electrostatically coupling the substrate to the dielectric first surface during use, wherein the dielectric first surface is sufficiently hydrophobic to electrostatically retain the substrate to the dielectric first surface when contacted with water.

2. The electrostatic chuck of claim 1, wherein the dielectric first surface comprises a hydrophobic coating or a super hydrophobic coating.

3. The electrostatic chuck of claim 2, wherein the dielectric first surface comprises the hydrophobic coating and the hydrophobic coating comprises silane, siloxane, or combinations thereof.

4. The electrostatic chuck of claim 2, wherein the dielectric first surface comprises the super hydrophobic coating and the super hydrophobic coating comprises branched polysilicate structures and hydrophobic ligands.

5. The electrostatic chuck of claim 1, wherein dielectric first surface is polished to a surface finish having a surface roughness (Ra) of about 8 microinches or below.

6. The electrostatic chuck of claim 1, wherein the electrostatic chuck is a portable electrostatic chuck configured to be handled and moved by substrate processing equipment.

7. The electrostatic chuck of claim 1, wherein the dielectric first surface has a contact angle in an amount of 100 to 170 degrees when contacted with water.

8. The electrostatic chuck of claim 1, wherein the dielectric first surface has a contact angle of at least 100 degrees, at least 110 degrees, at least 120 degrees, at least 130 degrees, at least 140 degrees, at least 150 degrees, at least 160 degrees, or at least 170 degrees when contacted with water.

9. The electrostatic chuck of claim 1, wherein the dielectric first surface has a substrate support surface area of about 100 mm² to about 3 m².

10. The electrostatic chuck of claim 1, wherein the base is configured to provide sufficient stiffness to the electrostatic chuck such that when an ultra-thin substrate is disposed on the electrostatic chuck, the ultra-thin substrate can be processed as a sheet in one or more process chambers.

11. The electrostatic chuck of claim 1, wherein the base is fabricated from at least one of glass, aluminum oxide (Al₂O₃), aluminum nitride (AlN), silicon (Si), stainless steel, aluminum, ceramic, or nickel iron alloy.

12. The electrostatic chuck of claim 1, wherein the base comprises a material that has a coefficient of thermal expansion similar to silicon.

13. The electrostatic chuck of claim 1, wherein base includes gas diffusion holes formed therethrough that fluidly couple a bottom surface of the base with the dielectric first surface.

14. The electrostatic chuck of claim 1, further comprising a power source coupled to the electrode to selectively provide power to the electrostatic chuck.

15. A method of electrostatically chucking an ultra-thin substrate, comprising:
electrostatically chucking a substrate to a base having a dielectric first surface to support a substrate thereon during processing and an electrode disposed within the base proximate the dielectric first surface to facilitate electrostatically coupling the substrate to the dielectric first surface during use, wherein the dielectric first surface is sufficiently hydrophobic to electrostatically retain the substrate to the base when contacted with water.

16. The method of claim 15, further comprising transporting the substrate from a first location to a second location.

17. The method of claim 15, further comprising:
applying a first power to the electrode to provide a bias base relative to the substrate;
contacting dielectric first surface and electrostatically retained substrate with water; and
performing a de-chucking process to release the substrate from the dielectric first surface.

18. The method of claim 17, wherein the de-chucking process includes:
providing a gas between the dielectric first surface and the substrate to release the substrate from the dielectric first surface.

19. The method of claim 15, wherein the substrate has a thickness of between about 10 to 200 microns.

20. An electrostatic chuck, comprising:
a base having a dielectric first surface to support a substrate thereon during processing; and
an electrode disposed within the base proximate the dielectric first surface to facilitate electrostatically coupling the substrate to the dielectric first surface during use, wherein the dielectric first surface is sufficiently hydrophobic to electrostatically retain the substrate to the dielectric first surface when contacted with water, wherein the dielectric first surface comprises a super hydrophobic coating comprising branched polysilicate structures and hydrophobic ligands, and wherein the dielectric first surface has a contact angle of at least 140 degrees when contacted with water.
